(19) United States
(12) Patent Application Publication
(10) Pub. No.: US 2026/0048585 A1
(43) Pub. Date: Feb. 19, 2026

(54) INKJET DEVICE DRIVE SYSTEM AND INKJET DEVICE

(71) Applicant: CHIA-HSIANG HUNG, TAIPEI CITY (TW)

(72) Inventors: XINZHE JIANG, Kunshan City (CN); WEI ZHAO, Kunshan City (CN); RUI TIAN, Kunshan City (CN); PEIPEI PU, Kunshan City (CN); JIANMIN LI, Kunshan City (CN); YONG WANG, Kunshan City (CN); WENFENG SHUAI, Kunshan City (CN)

(21) Appl. No.: 19/297,009

(22) Filed: Aug. 12, 2025

(30) Foreign Application Priority Data
Aug. 13, 2024 (CN) 202411110101.4

(51) Int. Cl. B41J 2/045; H03K 3/017; H03K 17/687

(52) U.S. Cl. CPC B41J 2/04591; B41J 2/04541; B41J 2/0455; B41J 2/04573; B41J 2/04586; B41J 2/04588; H03K 3/017; H03K 17/6871

(57) ABSTRACT

The present disclosure pertains to an inkjet drive system comprising a plurality of pulse width modulators (PWMs), a plurality of waveform switching circuits, a plurality of drive circuits, a control signal output circuit, and a plurality of nozzle groups. Each PWM outputs a distinct pulse waveform and is connected to all waveform switching circuits. Each switching circuit, under control of the control signal output circuit, selects a PWM waveform and supplies it to its associated drive circuit, which actuates the corresponding nozzle. This configuration enables independent, precise nozzle control, energy-saving operation, rapid nozzle unclogging, and compatibility with various printing materials, offering broad applicability in inkjet devices.

### CROSS-REFERENCE TO RELATED APPLICATIONS

This application claims the benefit of Chinese Invention patent application Ser. No. 202411110101.4, filed on 13 Aug. 2024, the entire disclosure of which is hereby incorporated by reference.

### BACKGROUND

The present disclosure relates to the field of inkjet devices, and in particular to a drive system for an inkjet device.

A drop on demand (DOD) inkjet device, also known as a valve-jet inkjet device, primarily uses compressed air to drive ink droplets onto the surface of products. Unlike other types of inkjet devices that require inks tailored to their specific printing mechanisms, the DOD inkjet device has a strong jetting capability and low requirements for ink, even supporting inks designed for other types of inkjet devices. An existing DOD inkjet device typically includes several solenoid valves. Because solenoid valves are inherently compliant mechanical components, maintaining consistent ink delivery is challenging. So a drive waveform needs to be set to guarantee consistency of each point. A drive waveform includes a drive voltage and drive duration. Due to the device's high power consumption and limited on-site voltage adjustability, the drive voltage is typically factory-preset. The waveform is changed mainly by adjusting the drive time, to fine tune a printing effect. It is difficult to implement fine control over a nozzle.

In existing solutions, only the drive time can be adjusted for drive waveform setting. Thus an adjustment capability is limited. Consequently, this greatly limits adaptability to operating conditions, and affects expansion of application scenarios. Because different inks have different viscosities, surface tension, and other characteristics, manufacturers often need to adjust parameters for the inkjet device on site according to ink specifications of clients. When inks are replaced, repeated field adjustment is required, which consumes time and effort.

The existing DOD inkjet device typically works independently and singly, and prints a character having a maximum width of 32 dots. If a wider character needs to be printed, the device prints back and forth after being transversely translated.

As application scenarios of the DOD inkjet device expand, higher requirements have been imposed on a printing scale and printing efficiency. 32-dot printing has far not met customer requirements. In a back-and-forth printing solution, a function of transverse movement of nozzles to be added, which has low efficiency, has complex operating conditions, is prone to faults. Printing precision is usually not high.

### SUMMARY

To solve one of the above problems, the present disclosure provides a drive system for an inkjet device, which at least implements independent and precise control over nozzles by a waveform, and at least solves a problem of limitation in timing control or solves a problem of difficulty in voltage and current control.
Implementation 1. A drive system for an inkjet device includes a plurality of pulse width modulators, a plurality of waveform switching circuits (or waveform selectors), a plurality of drive circuits, a plurality of groups of nozzles, and a control signal output circuit.

The plurality of pulse width modulators output different pulse waveforms respectively. Each pulse width modulator is connected to all the waveform switching circuits.

The plurality of waveform switching circuits select or switch one pulse waveform from the plurality of pulse width modulators according to control information provided by the control signal output circuit, and provide the pulse waveform as a drive waveform for a corresponding drive circuit, and then the drive circuit drives, according to the drive waveform, a corresponding nozzle to perform a printing operation.
Implementation 2. According to the drive circuits in Implementation 1, the control information includes time point information and a corresponding pulse width modulator. Thus the waveform switching circuits are able to switch, at a time point, the drive waveform to a pulse waveform provided by the corresponding pulse width modulator. The pulse waveform is a square wave.
Implementation 3. According to the drive circuits in Implementation 1, the plurality of pulse width modulators include three pulse width modulators. The three pulse width modulators respectively output three different pulse waveforms including a startup waveform, a holding waveform, and a release waveform. A duty cycle of the startup waveform is higher than a duty cycle of the holding waveform. The release waveform is an inverse waveform.
Implementation 4. According to the drive circuits in Implementation 1, the different pulse waveforms are square waves with different duty cycles.
Implementation 5. According to the drive system in Implementation 1, the different pulse waveforms at least include a waveform 1, a waveform 2, and a waveform 3. The waveform 1 is a waveform whose duty cycle is greater than or equal to 70% and less than or equal to 100%. The waveform 2 is a waveform whose duty cycle is greater than or equal to 10% and less than or equal to 30%. The waveform 3 is a waveform whose duty cycle is greater than or equal to 10% and less than or equal to 30%. The waveform 3 is an inverse waveform. A negative bias is used for accelerating resetting of the nozzles.
Implementation 6. According to the drive system in Implementation 5, viscosities of inks corresponding to the waveforms range from 1 cps to 1000 cps, and surface tension of the inks ranges 20 mN/m to 70 mN/m.
Implementation 7. According to the drive system in any one of Implementations 1 to 5, the three pulse width modulators output pulse waveforms to 8 to 40 waveform switching circuits respectively. The control signal output circuit provides and sends 8 to 40 paths of different control information to the 8 to 40 waveform switching circuits respectively.
Implementation 8. According to the drive system in any one of Implementations 1 to 5, the plurality of pulse width modulators include a pulse width modulator. The pulse width modulator outputs a high-frequency waveform to increase a frequency and a width of a pulse, or the pulse width modulator outputs a waveform whose duty cycle is greater than 98% to improve energy output of the nozzles. Thus when the nozzles are clogged, the waveform of the pulse width in modulator is used to impact the nozzles to implement unclogging.
Implementation 9. According to the drive system in any one of Implementations 1 to 5, the plurality of pulse width modulators at least use a pulse width modulation chip. The plurality of waveform switching circuits at least use an integrated analog switch. The plurality of drive circuits at least use a driver. The plurality of groups of nozzles at least use a metal-oxide-semiconductor (MOS) field effect transistor. An output pin of the pulse width modulation chip is connected to an input pin of the integrated analog switch. An output pin of the integrated analog switch is connected to an input pin of the driver. An output pin of the driver is connected to a gate of the MOS field effect transistor. A drain of the MOS field effect transistor is connected to the plurality of groups of nozzles.
Implementation 10. According to the drive system in any one of Implementations 1 to 5, a working state of the nozzles is controlled by solenoid valves arranged in the nozzles. The control signal output circuit communicates with a host computer.

The present disclosure has at least one of the following beneficial effects:

Through independent and precise control over the nozzles by the waveforms, the problem of limitation in timing control and difficulty in voltage and current control are solved. Fine or consistent independent control is implemented. A further effect is adaptability to different printing materials. Further, the nozzles may be finely controlled through pulse width modulation in combination with software. Furthermore, rapid starting of the nozzles and unclogging of the nozzles are implemented; or energy consumption is reduced, and a problem of high control energy consumption is controlled.

A lower duty cycle is used to reduce power consumption, and an effect of energy saving is achieved. In a case that it is difficult to achieve the effect of energy saving by controlling a voltage and a current in prior art, and the lower duty cycle reduces the power consumption, reduces heat generation, and prolongs service life; or the release waveform drives the nozzles, to generate a release signal, and the bias voltage accelerates the resetting of the nozzles, to generate the release signal, such that a working frequency is increased.

Furthermore, especially applicable to a case that the nozzles are clogged, the waveform switching circuits select the startup waveform or the holding waveform according to an actual situation to implement applicability to different printing materials, such that compatibility of a printing head and a printing effect can be improved. During actual application, the switching circuits need to automatically select an appropriate waveform according to factors of a characteristic of a printing material and a clogging degree of the nozzles, to guarantee printing quality.

### BRIEF DESCRIPTION OF THE DRAWINGS

In order to explain the technical solutions in embodiments of the present disclosure more clearly, the accompanying drawings of the embodiments will be described below briefly. Apparently, the accompanying drawings in the following description merely relates to some embodiments of the present disclosure, and are not limiting of the present disclosure.

FIG. 1 is a schematic diagram of a drive system for an inkjet device according to an embodiment of the present disclosure; and

FIG. 2 is a comparison diagram of a waveform of a solution in the present disclosure according to an embodiment of the present disclosure and an existing waveform.

### DETAILED DESCRIPTION

To make the objectives, technical solutions, and advantages in embodiments of the present disclosure clearer, the technical solutions in the embodiments of the present disclosure are clearly and completely described below with reference to the accompanying drawings in the embodiments of the present disclosure. Apparently, the embodiments described are some embodiments rather than all embodiments of the present disclosure. Based on the embodiments in the present disclosure, all other embodiments derived by those of ordinary skill in the art without creative efforts fall within the protection scope of the present disclosure.

To make the objectives, the technical solutions, and the advantages of the present disclosure clearer, the specific embodiments of the present disclosure are further described in detail with reference to the accompanying drawings, and the embodiments do not constitute a limitation to the embodiments of the present disclosure.

As for description of related technical terms in the present disclosure, without special description in the present disclosure, the “control information” and the “control signal” are the same technical terms. The “provided by the pulse width modulator” and the “outputs by the pulse width modulator” are a same technical term. In the present disclosure, one or more than three nozzles may be provided in each group.

The present disclosure provides a drive system for an inkjet device. The drive system includes a plurality of pulse width modulators, a plurality of waveform switching circuits, a plurality of drive circuits, a plurality of groups of nozzles, and a control signal output circuit.

The plurality of pulse width modulators output different pulse waveforms respectively. Each pulse width modulator is connected to all the waveform switching circuits.

The plurality of waveform switching circuits select or switch one pulse waveform from the plurality of pulse width modulators according to control information provided by the control signal output circuit, and provide the pulse waveform as a drive waveform for a corresponding drive circuit, and then the drive circuit drives, according to the drive waveform, a corresponding nozzle to perform a printing operation. Accordingly, through independent and precise control over the nozzles by the waveforms, the problem of limitation in timing control and difficulty in voltage and current control are solved. A further effect is adaptability to different printing materials. Further, rapid starting of the nozzles and unclogging of the nozzles are implemented; or energy consumption is reduced, and a problem of high control energy consumption is controlled.

In some implementations, the control information includes time point information and a corresponding pulse width modulator. Thus the waveform switching circuits are able to switch, at a time point, the drive waveform to a pulse waveform provided by the corresponding pulse width modulator. The pulse waveform is a square wave.

In some implementations, the plurality of pulse width modulators include three pulse width modulators. The three pulse width modulators respectively output three different pulse waveforms including a startup waveform, a holding waveform, and a release waveform. A duty cycle of the startup waveform is higher than a duty cycle of the holding waveform. The release waveform is an inverse waveform. Thus drive signals of waveforms at different drive phases can be provided. The startup waveform drives the nozzles, to generate a startup signal for starting the nozzles. The holding waveform drives maintenance of stable working of the nozzles, to generate a holding signal for maintaining working of the nozzles. The release waveform drives the nozzles, to generate a release signal.

In some implementations, the different pulse waveforms are square waves with different duty cycles. Duty cycles and periods of the waveforms output by the three pulse width modulators may be independently set to improve flexibility and high efficiency of waveform control.

In some implementations, the different pulse waveforms at least include a waveform 1, a waveform 2, and a waveform 3. The waveform 1 is a waveform whose duty cycle is greater than or equal to 70% and less than or equal to 100%, and is the startup waveform. The waveform 2 is a waveform whose duty cycle is greater than or equal to 10% and less than or equal to 30%, and is the holding waveform. The waveform 3 is a waveform whose duty cycle is greater than or equal to 10% and less than or equal to 30%. The waveform 3 is an inverse waveform, and may be used as the release waveform. A bias voltage is used for accelerating resetting of the nozzles. An effect of energy saving of the present disclosure is reflected. The effect of energy saving is achieved through waveform control. In a case that it is difficult to achieve the effect of energy saving by controlling a voltage and a current in prior art, specifically, a higher duty cycle outputs high energy, and a lower duty cycle reduces power consumption, reduces heat generation, and prolongs service life. The bias voltage may accelerate the resetting of the nozzles and increase a working frequency. The resetting of the nozzles is accelerated by using the bias voltage, to generate a release signal for release of the nozzles. The high-frequency waveform may be the holding waveform or the startup waveform. When the high-frequency waveform used for intensively impacting a blockage substance is the startup waveform, the high-frequency waveform is used for exciting or activating liquid in a nozzle, such that the liquid quickly forms a high-velocity jet fluid. Energy provided by the high-frequency waveform makes the liquid sharply compress and expand to form a high-velocity jet flow. Thus the blockage substance is effectively removed.

In some implementations, viscosities of inks corresponding to the waveforms range from 1 cps to 1000 cps, and surface tension of the inks ranges 20 mN/m to 70 mN/m. When the high-frequency waveform acts as the holding waveform, features of the signal, such as a frequency, an amplitude, and a phase, are held in a transmission process. By adjusting parameters (such as a frequency, an amplitude, and a shape) of the high-frequency waveform, performance of the jet liquid can be optimized. Jetting efficiency is improved. Efficiency of removing the blockage substance can be improved. The high-frequency waveform may increase intermolecular distances in the liquid, to reduce the viscosity of the liquid and improve flow properties of the liquid.

In some implementations, the three pulse width modulators output pulse waveforms to 8 to 40 waveform switching circuits respectively. The control signal output circuit provides and sends 8 to 40 paths of different control information to the 8 to 40 waveform switching circuits respectively.

In some implementations, the plurality of pulse width modulators include a pulse width modulator. The pulse width modulator outputs a high-frequency waveform to increase a frequency and a width of a pulse, or the pulse width modulator outputs a waveform whose duty cycle is greater than 98% to improve energy output of the nozzles. Thus when the nozzles are clogged, the waveform of the pulse width modulator is used to impact the nozzles to implement unclogging. When the nozzles are clogged by the printing material, the pulse width modulator outputs the high-frequency waveform to increase the frequency and width of the pulse, and a higher duty cycle is increased to improve the energy output of the nozzles. The blockage substance is impacted to exit from a jetting hole. An unclogging effect of the pulse of the waveform according to the present disclosure is achieved.

In some implementations, the plurality of pulse width modulators at least use a pulse width modulation chip. The plurality of waveform switching circuits at least use an integrated analog switch. The plurality of drive circuits at least use a driver. The plurality of groups of nozzles at least use a metal-oxide-semiconductor (MOS) field effect transistor. An output pin of the pulse width modulation chip is connected to an input pin of the integrated analog switch. An output pin of the integrated analog switch is connected to an input pin of the driver. An output pin of the driver is connected to a gate of the MOS field effect transistor. A drain of the MOS field effect transistor is connected to the plurality of groups of nozzles.

In some implementations, a working state of the nozzles is controlled by solenoid valves arranged in the nozzles. The control signal output circuit communicates with a host computer.

In some implementations, the present disclosure further provides a flow method of working of a circuit of an inkjet device. First, each pulse width modulator provides or outputs different waveforms (pulse waveforms) to the plurality of waveform switching circuits.

For example, in a working process of the inkjet device, different waveforms (pulse waveforms) are provided by the pulse width modulators at different phases of driving. Specifically, the pulse width modulators may include a first pulse width modulator, a second pulse width modulator, and a third pulse width modulator. The first pulse width modulator, the second pulse width modulator, and the third pulse width modulator provide different waveforms for the plurality of waveform switching circuits respectively.

For example, the first pulse width modulator outputs a first waveform. The first waveform is the startup waveform for starting the nozzles. The second pulse width modulator outputs a second waveform. The second waveform is the holding waveform for maintaining working of the nozzles. The third pulse width modulator outputs a third waveform. The third waveform is the release waveform for release of the nozzles. According to some embodiments, duty cycles and period time of the three different waveforms are independently set. The duty cycle of the first waveform is greater than the duty cycle of the second waveform.

Second, the control signal output circuit provides independent control signals or control information for the plurality of waveform switching circuits respectively.

The control signal output circuit receives an instruction of a system and transmits the instruction to a corresponding waveform switching circuit. The plurality of waveform switching circuits are connected to each other in parallel. The control signal output circuit may provide different control signals or information for the plurality of waveform switching circuits, such that each waveform switching circuit can select or switch one pulse waveform from the plurality of pulse width modulators, or the plurality of waveform switching circuits may be independently controlled.

Further, the plurality of waveform switching circuits at least provide the pulse waveforms as drive waveforms for the drive circuits corresponding to the plurality of waveform switching circuits.

For example, the plurality of waveform switching circuits select or switch, at least according to the control signals or the control information provided by the control signal output circuit, waveforms (pulse waveforms) provided or output by the pulse width modulators, and transmit the selected or switched waveforms as the drive waveforms to the plurality of drive circuits. The plurality of drive circuits output amplified waveform signals respectively according to the waveforms (drive waveforms) provided by the plurality of waveform switching circuits.

Finally, the plurality of drive circuits drive the plurality of groups of nozzles respectively.

The plurality of drive circuits control the solenoid valves in the plurality of groups of nozzles respectively. The drive circuits perform voltage amplification on the waveforms provided by the waveform switching circuits, to generate sufficiently large currents to drive the solenoid valves. Further, the plurality of drive circuits respectively drive the plurality of groups of nozzles to complete printing work.

A working process of a drive system of the entire inkjet device provides waveforms at different phases for the pulse width modulators, and transmits the drive signals of the waveforms at different phases to the plurality of waveform switching circuits. The plurality of waveform switching circuits select suitable drive waveforms according to the signals provided by the control signal output circuit. Then the nozzles are controlled by the drive circuits to implement printing.

The present disclosure is more specifically exemplified by using the following embodiments.

### EMBODIMENT

### Embodiment 1

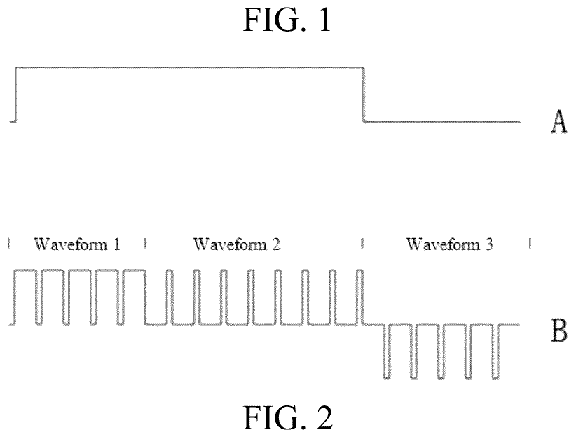

As shown in FIG. 1, the embodiment shows a schematic diagram of a drive system for an inkjet device. In the embodiment, the present disclosure is described by using 32 waveform switching circuits. The drive system for an inkjet device includes components of 3 pulse width modulators, 32 waveform switching circuits, a control signal output circuit, 32 drive circuits, and 32 groups of nozzles. The 3 pulse width modulators 10 include pulse width modulators 01-1, 01-2, and 01-3. The 32 waveform switching circuits 20 include waveform switching circuits 02-1, 02-2, . . . , and 02-32. The control signal output circuit is a control signal output circuit 05. The 32 drive circuits 30 include drive circuits 03-1, 03-2, . . . , and 03-32. The 32 groups of nozzles 4 include nozzles 4-1, 4-2, . . . , and 4-32. The 3 pulse width modulators include a first pulse width modulator 01-1, a second pulse width modulator 01-2, and a third pulse width modulator 01-3.

Each of the first pulse width modulator 01-1, the second pulse width modulator 01-2, and the third pulse width modulator 01-3 is electrically connected to the plurality of waveform switching circuits 02-1, 02-2 to 02-32. The 32 waveform switching circuits 02-1, 02-2 to 02-32 are connected to 32 drive circuits 03-1, 03-2 to 03-32 respectively. The 32 drive circuits 03-1, 03-2 to 03-32 are electrically connected to the 32 groups of nozzles 4-1, 4-2 to 4-32 respectively, to drive the 32 groups of nozzles to implement printing.

An output of the control signal output circuit 05 is electrically connected to the plurality of waveform switching circuits 02-1, 02-2 to 02-32 separately, to provide independent control information or signals for the plurality of waveform switching circuits 02-1, 02-2 to 02-32 separately. The 32 groups of nozzles form a nozzle array. A working state of the nozzles is controlled by solenoid valves arranged in the nozzles. The control signal output circuit communicates with a host computer.

The control information includes time point information and a waveform provided by a corresponding pulse width modulator. Thus the waveform switching circuits are able to switch, at a time point, a drive waveform to a pulse waveform provided by the corresponding pulse width modulator.

A schematic diagram of a drive system for an inkjet device is shown. In the embodiment, the present disclosure is described by using 32 waveform switching circuits. The drive system for an inkjet device includes components of 3 pulse width modulators, 32 waveform switching circuits, a control signal output circuit, 32 drive circuits, and 32 groups of nozzles. The 3 pulse width modulators 10 include pulse width modulators 01-1, 01-2, and 01-3. The 32 waveform switching circuits 20 include waveform switching circuits 02-1, 02-2, . . . , and 02-32. The control signal output circuit is a control signal output circuit 05. The 32 drive circuits 30 include drive circuits 03-1, 03-2, . . . , and 03-32. The 32 groups of nozzles 4 include nozzles 4-1, 4-2, . . . , and 4-32. The 3 pulse width modulators include a first pulse width modulator 01-1, a second pulse width modulator 01-2, and a third pulse width modulator 01-3.

Each of the first pulse width modulator 01-1, the second pulse width modulator 01-2, and the third pulse width modulator 01-3 is electrically connected to the plurality of waveform switching circuits 02-1, 02-2 to 02-32. The 32 waveform switching circuits 02-1, 02-2 to 02-32 are connected to 32 drive circuits 03-1, 03-2 to 03-32 respectively. The 32 drive circuits 03-1, 03-2 to 03-32 are electrically connected to the 32 groups of nozzles 4-1, 4-2 to 4-32 respectively, to drive the 32 groups of nozzles to implement printing.

An output of the control signal output circuit 05 is electrically connected to the plurality of waveform switching circuits 02-1, 02-2 to 02-32 separately, to provide independent control information or signals for the plurality of waveform switching circuits 02-1, 02-2 to 02-32 separately. The 32 groups of nozzles form a nozzle array. A working state of the nozzles is controlled by solenoid valves arranged in the nozzles. The control signal output circuit communicates with a host computer.

The control information includes time point information and a waveform provided by a corresponding pulse width modulator. Thus the waveform switching circuits are able to switch, at a time point, a drive waveform to a pulse waveform provided by the corresponding pulse width modulator.

Each of the three pulse width modulators provides or outputs pulse waveforms at three different phases to at least 32 waveform switching circuits. The control signal output circuit provides and sends at least 32 paths of different control information to the at least 32 waveform switching circuits respectively.

The at least 32 waveform switching circuits receive three waveforms sent by the three pulse width modulators.

The at least 32 waveform switching circuits receive the at least 32 paths of control information sent by a control signal output circuit, switch three waveforms according to a parameter, for example, different time points, set by the control information, and provide the three switched waveforms as drive waveforms for corresponding drive circuits, or send the at least 32 switched control signals to the at least 32 drive circuits.

The at least 32 drive circuits receive the three switched waveforms or the at least 32 switched control signals sent by the at least 32 waveform switching circuits, drive and amplify the three waveforms (drive waveforms) or the at least 32 control signals that are switched or selected, output a signal, and send the signal to the at least 32 groups of nozzles.

The at least 32 groups of nozzles perform printing according to the at least 32 received signals respectively. Thus the at least 32 groups of nozzles are independently controlled.

The 32 groups of nozzles 4 are also controlled as follows: the control waveform switching circuit is set by software to provide a waveform model control signal or information for the 32 groups of nozzles 4. Independent and precise control over nozzles by the waveforms is implemented. A problem of limitation in timing control and difficulty in voltage and current control are solved. Fine or consistent independent control is implemented.

Further, the control signal output circuit further performs data communication with the host computer, and receives a control signal, character data, and picture data sent by the host computer. The plurality of waveform switching circuits include a plurality of multiplexers.

### Embodiment 2

The embodiment shows waveforms and their related effects involved in the present disclosure. FIG. 2 is a schematic diagram of 3 different waveforms respectively output by 3 pulse width modulators provided in the embodiment and a waveform output by a pulse width modulator in the prior art. A in FIG. 2 shows the waveform output by the pulse width modulator in the prior art, and B shows the waveforms in a solution of the present disclosure, and is preferably square waves. Each pulse width modulator provided in the embodiment of the present disclosure outputs one waveform (pulse waveform). The 3 pulse width modulators respectively output 3 different waveforms including a waveform 1 being a startup waveform, a waveform 2 being a holding waveform, and a waveform 3 being a release waveform. A startup signal is generated when the startup waveform drives nozzles. A higher duty cycle of the startup waveform corresponds to high-energy output. The holding waveform drives maintenance of stable working of the nozzles, to generate a corresponding holding signal. A lower duty cycle of the holding waveform reduces power consumption, and has an effect of energy saving. The effect of energy saving is achieved through waveform control. In a case that it is difficult to achieve the effect of energy saving in the present disclosure by controlling a voltage and a current in prior art, the release waveform drives the nozzles, to generate a release signal, and a bias voltage accelerates the resetting of the nozzles, to generate the release signal, such that a working frequency is increased.

B shows 3 different waveforms output by the 3 pulse width modulators respectively. The waveform 1 is a waveform whose duty cycle is greater than or equal to 80% and less than or equal to 98%. The waveform 2 is a waveform whose duty cycle is greater than or equal to 12% and less than or equal to 28%. The waveform 3 is a waveform whose duty cycle is greater than or equal to 12% and less than or equal to 29%. The waveform 3 is an inverse waveform. The negative bias accelerates the resetting of the nozzles. Duty cycles of the different waveforms are used for at least achieving one of effects such as energy saving, energy consumption reducing, power consumption reducing through a lower duty cycle, heat generation reducing, and service life prolonging.

Further, the foregoing three pulse width modulators output three waveforms with different duty cycles respectively, to control the nozzles. The waveform 1 is the startup waveform. In a startup phase of the nozzles, higher energy output is needed to activate the nozzles. The higher duty cycle of the startup waveform means that within unit time, the nozzles keep in an on state for long time. The startup waveform is applicable to a high-precision application requiring continuous jetting. The number of times of output of high-energy pulses is large, such that the nozzles can quickly reach a working state. The waveform is conducive to startup time shortening, and a response speed of the nozzles is improved.

Specifically, the waveform 2 is the holding waveform, and is a waveform used for maintaining normal working of the nozzles. In a working phase of the nozzles, the lower duty cycle can reduce the power consumption, reduce the heat generation, and prolong the service life of the nozzles. The holding waveform needs to hold stable working of the nozzles, so as to guarantee printing quality. The holding waveform may reduce energy consumption and maintenance cost of an apparatus while guaranteeing a printing effect.

Specifically, the waveform 3 is the release waveform, and is also the inverse waveform. In a release phase of the nozzles, the negative bias may accelerate the resetting of the nozzles, such that the nozzles can quickly return to initial positions. The release waveform contributes to increase in the working frequency of the nozzles, shortening of interval time, and improvement in the printing efficiency. Moreover, the foregoing negative-voltage solution at least has the negative bias, such that wear of the nozzles can also be reduced in a release process, and service life of the nozzles can be prolonged. The inverse waveform can reduce a voltage fluctuation during startup and shutdown of the nozzles, to reduce a risk of damage to the nozzles.

As for other effects of the embodiment of the present disclosure, by using the three waveforms with different duty cycles, a jetting state of the nozzles can be flexibly controlled according to actual application requirements, such that an efficient and accurate jetting effect is achieved. Duty cycles and period time of the waveforms output by the 3 pulse width modulators are all independently set. In an actual application, the duty cycles of the three waveforms need to be adjusted according to a specific scenario and apparatus parameters, to achieve an optimal control effect.

Specifically, the lower duty cycle is used to reduce the power consumption, and the effect of energy saving is achieved. In a case that it is difficult to achieve the effect of energy saving by controlling a voltage and a current in prior art, and the lower duty cycle reduces the power consumption, reduces the heat generation, and prolongs the service life; or the release waveform drives the nozzles, to generate the release signal, and the negative biasaccelerates the resetting of the nozzles, to generate the release signal, such that the working frequency is increased.

Furthermore, especially applicable to a case that the nozzles are clogged, the waveform switching circuits select the startup waveform or the holding waveform according to an actual situation to implement applicability to different printing materials, such that compatibility of a printing head and a printing effect can be improved. During actual application, the switching circuits need to automatically select an appropriate waveform according to factors of a characteristic of a printing material and a clogging degree of the nozzles, to guarantee printing quality. A waveform situation of the present disclosure is described in detail below. When the nozzles are clogged by the printing material, the waveform switching circuits switch to the startup waveform, and a high jetting pressure is rapidly generated when the startup waveform is switched, and the clogging printing material is impacted and removed. Such a waveform is applicable to various printing materials since large force may be generated in short time to remove the clogging printing material.

The present disclosure provides a manner of rapid and efficient clogging removal by a waveform pulse after a nozzle is clogged and a waveform application manner. When the nozzles are clogged, a high-frequency waveform output by the pulse width modulator is adjusted to increase a frequency and width of a pulse, and/or a higher duty cycle is increased to improve energy output of the nozzles. A blockage substance is impacted to exit from a jetting hole, such that unclogging is implemented by impacting the nozzles. Preferably, by increasing a drive voltage and time, intensively impacting is performed by using the high-frequency waveform, the blockage substance can be impacted, and then the blockage substance exits from the jetting hole. However, an excessively high duty cycle may cause overheat or damage to the nozzles. Thus adjustment needs to be performed within a safe range.

Moreover, the startup waveform causes a large jetting fluctuation in a printing process, and this may influence printing quality. Accordingly, in a normal printing process, the startup waveform should not be used for long time. Compared with the startup waveform, a jetting pressure generated by the holding waveform is smaller, and a stable jetting effect can be maintained in a printing process. The holding waveform is applicable to various printing materials, but may have a poorer effect than the startup waveform in unclogging. When the nozzles are clogged by a printing material, the waveform switching circuits select the startup waveform or the holding waveform according to an actual situation, to achieve applicability to different printing materials. The startup waveform is applicable to unclogging. The holding waveform is applicable to maintaining normal working of the nozzles.

### Embodiment 3

The embodiment shows electronic components mainly used in a drive system of an inkjet device and a connection relationship of the electronic components. A plurality of pulse width modulators at least use a pulse width modulation chip. A plurality of waveform switching circuits at least use an integrated analog switch. A plurality of drive circuits at least use a driver. A plurality of groups of nozzles at least use an MOS field effect transistor. An output pin of the pulse width modulation chip is connected to an input pin of the integrated analog switch. An output pin of the integrated analog switch is connected to an input pin of the driver. An output pin of the driver is connected to a gate of the MOS field effect transistor. A drain of the MOS field effect transistor is connected to the plurality of groups of nozzles. Preferably, the pulse width modulators implement functions by using a chip M451. The waveform switching circuits implement a main function by at least using an integrated analog switch SN74LVC1G126DBV. The drive circuits use a driver MCP1416. The nozzles at least use an MOS field effect transistor NCE6020AK. A pulse width modulation (PWM) output pin of the pulse width modulation chip M451 is connected to an input pin of the analog switch. An output pin of the analog switch is connected to an input pin of the driver MCP1416. An output pin of the MCP1416 is connected to a gate of the MOS field effect transistor. A drain of the MOS field effect transistor is connected to the nozzles.

In the present disclosure, pulse width modulation is a solution used for controlling output of an alternating current power supply or a direct current power supply. By changing a width of a pulse, an output voltage or current may be controlled. An appropriate width of the pulse is calculated and set according to a waveform requirement. Parameters such as a duty cycle and a frequency of the pulse width modulators are set. By changing the width of the pulse, power control is implemented on a heating element.

The control signal output circuit writes a control program, and burns the written program into the waveform switching circuits to control three waveforms. Output of the pulse width modulators is adjusted in real time according to a printing task and a state of the nozzles. In an actual application process, a working state of the nozzles is monitored in real time. Waveform parameters are adjusted according to actual requirements. The nozzles are driven to work according to a set waveform, to achieve a better printing effect.

### Embodiment 4

The embodiment shows selection and matching of a waveform and a corresponding ink for a drive system of the present disclosure. The drive system of the present disclosure has applicability to different printing materials, and can improve compatibility of a printing head and a printing effect. Preferred matching of different waveforms of the device of the present disclosure and corresponding inks is shown in Table 1.

Table 1 shows preferred matching of different waveforms of the drive system of the present disclosure and corresponding inks

| | Ink property | | Second pulse width | | First pulse width | | Third pulse width | |
|---|---|---|---|---|---|---|---|---|
| | parameter | | modulator | | modulator | | modulator | |
| | | Surface | | Duty | | Duty | | Duty |
| Ink | Viscosity | tension | Frequency | cycle | Frequency | cycle | Frequency | cycle |
| name | (cps) | (mN/m) | (Hz) | (%) | (Hz) | (%) | (Hz) | (%) |
| Ink 1 | 2.5 | 23 to 25 | 1000 | 12.5 | 1000 | 70 | 1000 | 12 |
| Ink 2 | 4.9 | 27 to 29 | 1000 | 20 | 1000 | 80 | 1000 | 12 |
| Ink 3 | 14.5 | 24 to 27 | 600 | 30 | 600 | 80 | 600 | 12 |
| Ink 4 | 5.7 | 23 to 25 | 600 | 15 | 600 | 70 | 600 | 12 |

In the foregoing embodiment, ink 1 is referred to as “water-based black ink”. Ink 2 is referred to as “water-based white ink”. Ink 3 is referred to as “water-based high-adhesion white ink”. Ink 4 is referred to as “water-based white ink”. They can be purchased on the market according to their property parameters. A plurality of first pulse width modulators and second pulse width modulators in the present disclosure may be provided. The first pulse width modulators and the second pulse width modulators respectively correspond to inks having different viscosities and surface tension.

In an actual application, the switching circuits need to automatically select an appropriate waveform according to factors such as characteristics of the printing materials and a clogging degree of the nozzles, to guarantee printing quality. Optionally, the foregoing printing materials are printing inks. The printing inks include a new material such as a pigment, a medicine, a binder, and nano-silver.

Those skilled in the art should further conceive that units and algorithm steps of each instance described in combination with the embodiments disclosed herein can be implemented by electronic hardware, computer software, or their combination. In order to clearly illustrate the interchangeability of hardware and software, compositions and steps of each instance have been generally described in terms of functions in the description described above. Whether these functions are performed by hardware or software depends on specific application of the technical solutions and design restriction conditions. Those skilled can implement the described functions with different methods for each particular application, but such implementation should not be considered to fall beyond the scope of the embodiments of the present disclosure.

The steps of the method or an algorithm described in conjunction with the embodiments disclosed herein may be implemented with hardware, a software module performed by a processor, or a combination of the hardware and the software module. The software module may be placed in a random access memory (RAM), a memory, a read only memory (ROM), an electrically programmable ROM, an electrically erasable programmable ROM, a register, a hard disk, a removable disk, a compact disc read-only memory (CD-ROM), or a storage medium in any other form known in the technical field.

The foregoing specific implementations describe the embodiments, the technical solutions, and the beneficial effects of the present disclosure in further detail. It should be understood that the foregoing descriptions are merely specific implementations of the embodiments of the present disclosure, but are not intended to limit a protection scope of the embodiments of the present disclosure. Any modification, equivalent replacement, or improvement made within the spirit and principle of the embodiments of the present disclosure shall fall within the protection scope of the embodiments of the present disclosure.

What is claimed is:

1. A drive system for an inkjet device, comprising a plurality of pulse width modulators, a plurality of waveform switching circuits, a plurality of drive circuits, a plurality of groups of nozzles, and a control signal output circuit,
wherein the plurality of pulse width modulators output different pulse waveforms respectively, and each pulse width modulator is connected to all the waveform switching circuits; and
the plurality of waveform switching circuits select or switch one pulse waveform from the plurality of pulse width modulators according to control information provided by the control signal output circuit, and provide the pulse waveform as a drive waveform for a corresponding drive circuit, and then the drive circuit drives, according to the drive waveform, a corresponding nozzle to perform a printing operation.

2. The drive system according to claim 1, wherein the control information comprises time point information and a corresponding pulse width modulator, then the waveform switching circuits are able to switch, at a time point, the drive waveform to a pulse waveform provided by the corresponding pulse width modulator, and the pulse waveform is a square wave.

3. The drive system according to claim 1, wherein the plurality of pulse width modulators comprise three pulse width modulators, the three pulse width modulators respectively outputting three different pulse waveforms comprising a startup waveform, a holding waveform, and a release waveform, a duty cycle of the startup waveform is higher than a duty cycle of the holding waveform, and the release waveform is an inverse waveform.

4. The drive system according to claim 1, wherein the different pulse waveforms are square waves with different duty cycles.

5. The drive system according to claim 1, wherein the different pulse waveforms at least comprise a waveform 1, a waveform 2, and a waveform 3, the waveform 1 being a waveform whose duty cycle is greater than or equal to 70% and less than or equal to 100%, the waveform 2 being a waveform whose duty cycle is greater than or equal to 10% and less than or equal to 30%, the waveform 3 being a waveform whose duty cycle is greater than or equal to 10% and less than or equal to 30%, and the waveform 3 being an inverse waveform, and a negative bias is used for accelerating resetting of the nozzles.

6. The drive system according to claim 5, wherein viscosities of inks corresponding to the waveforms range from 1 cps to 1000 cps, and surface tension of the inks ranges 20 mN/m to 70 mN/m.

7. The drive system according to claim 1, wherein the three pulse width modulators output pulse waveforms to 8 to 40 waveform switching circuits respectively; and the control signal output circuit provides and sends 8 to 40 paths of different control information to the 8 to 40 waveform switching circuits respectively.

8. The drive system according to claim 1, wherein the plurality of pulse width modulators comprise a pulse width modulator, the pulse width modulator outputting a high-frequency waveform to increase a frequency and a width of a pulse, or the pulse width modulator outputting a waveform whose duty cycle is greater than 98% to improve energy output of the nozzles, and when the nozzles are clogged, the waveform of the pulse width modulator is used to impact the nozzles to implement unclogging.

9. The drive system according to claim 1, wherein the plurality of pulse width modulators at least use a pulse width modulation chip, the plurality of waveform switching circuits at least use an integrated analog switch, the plurality of drive circuits at least use a driver, the plurality of groups of nozzles at least use a metal-oxide-semiconductor (MOS) field effect transistor, an output pin of the pulse width modulation chip is connected to an input pin of the integrated analog switch, an output pin of the integrated analog switch is connected to an input pin of the driver, an output pin of the driver is connected to a gate of the MOS field effect transistor, and a drain of the MOS field effect transistor is connected to the plurality of groups of nozzles.

10. The drive system according to claim 1, wherein a working state of the nozzles is controlled by solenoid valves arranged in the nozzles, and the control signal output circuit communicates with a host computer.

11. An inkjet device, using the drive system according to claim 1.
